(19) United States
(12) Patent Application Publication
(10) Pub. No.: US 2025/0380570 A1
(43) Pub. Date: Dec. 11, 2025

(54) LIGHT EMITTING DEVICE, AND IMAGE FORMING APPARATUS

(71) Applicant: CANON KABUSHIKI KAISHA, Tokyo (JP)

(72) Inventors: MIZUKI NAGASAKI, Kanagawa (JP); NAOKI ISODA, Tokyo (JP); TATSUYA RYOKI, Kanagawa (JP)

(21) Appl. No.: 19/227,211

(22) Filed: Jun. 3, 2025

(30) Foreign Application Priority Data
Jun. 10, 2024 (JP) 2024-093958

(51) Int. Cl. H10K 59/121; B41J 2/45; B41J 2/47; G03G 15/04; G03G 15/041; H10K 59/80

(52) U.S. Cl. CPC H10K 59/1213; B41J 2/451; B41J 2/47; G03G 15/04036; G03G 15/0415; H10K 59/879

(57) ABSTRACT

A light emitting device includes a plurality of light emitting elements arranged on a main surface of a substrate in M columns and N rows (M and N are integers of one or more), and a plurality of pixel drive circuits arranged in M columns and N rows and configured to drive a corresponding light emitting element among the plurality of light emitting elements. The N rows and M columns extend in a first and second directions, respectively. A first array pitch of a first light emitting element and a second light emitting element adjacent to each other in the first direction parallel to the N rows among the plurality of light emitting elements is different from a second array pitch of a first pixel drive circuit and a second pixel drive circuit adjacent to each other in the first direction among the plurality of pixel drive circuits.

### BACKGROUND

### Field of the Disclosure

The present disclosure relates to a light emitting device, for example, a light emitting device provided with a light emitting element.

### Description of the Related Art

An optical writing device (an organic light emitting diode print head, OLED-PH) has been proposed that uses an organic light emitting diode (OLED) serving as a light emitting source and is used in an image forming apparatus. An OLED-PH is advantageous in miniaturization and cost reduction because an OLED and a transistor that drives the OLED can be formed on the same substrate. Particularly, in a case where a silicon wafer is used for a substrate, it is possible to finely form a drive circuit, and as a result, high density of the OLED serving as a light emitting source can be achieved. It is accordingly possible to form a high definition image.

Japanese Patent Application Laid-Open No. 2022-96966 discusses an OLED-PH in which a plurality of rectangular light emitting devices each including a plurality of OLEDs is arranged in a line. An amount of light emitted by one light emitting element using an OLED as a light emitting source of an image forming apparatus is not sufficient as the light emitting source in some cases. Japanese Patent Application Laid-Open No. 2022-96966 thus discusses a configuration in which a plurality of light emitting elements emits light to the same portion on a surface of a photosensitive member to supplement an amount of light required to form an electrostatic latent image on the surface of the photosensitive member.

Japanese Patent Application Laid-Open No. 2022-96966 does not discuss a positional relationship between the light emitting element and a pixel driving circuit for driving the light emitting element in detail.

### SUMMARY

According to an exemplary aspect, a light emitting device includes a plurality of light emitting elements arranged on a main surface of a substrate in M columns and N rows, and a plurality of pixel drive circuits arranged in M columns and N rows and configured to drive a corresponding light emitting element among the plurality of light emitting elements. M and N are integers greater than or equal to one. The N rows extend in a first direction and the M columns extend in a second direction. A first array pitch of a first light emitting element and a second light emitting element adjacent to each other in the first direction parallel to the N rows among the plurality of light emitting elements is different from a second array pitch of a first pixel drive circuit and a second pixel drive circuit adjacent to each other in the first direction among the plurality of pixel drive circuits.

According to another exemplary aspect, a light emitting device includes a plurality of light emitting elements arranged on a main surface of a substrate in a matrix, and a plurality of pixel drive circuits arranged in a matrix and each including a transistor configured to drive a corresponding light emitting element among the plurality of light emitting elements, and a current control circuit adjacent to a part of the plurality of pixel drive circuits in a first direction in a plan view with respect to the main surface. In the plan view, at least a part of the plurality of light emitting elements overlaps with the current control circuit.

Further features of the present disclosure will become apparent from the following description of exemplary embodiments with reference to the attached drawings.

### BRIEF DESCRIPTION OF THE DRAWINGS

FIG. 1A is a perspective view of an example of a photosensitive drum and an exposure head. FIG. 1B is a cross-sectional view of an example of the photosensitive drum and the exposure head illustrated in FIG. 1A.

FIGS. 2A to 2C illustrate an example of a printed substrate included in the exposure head.

FIG. 3 is a cross-sectional view of an example of a light emitting device according to one ore more aspects of the present disclosure.

FIG. 4 is a block diagram illustrating an example of the light emitting device according to one or more aspects of the present disclosure.

FIG. 5 illustrates an example of a pixel drive circuit according to one or more aspects of the present disclosure.

FIG. 6 illustrates an example of a circuit arrangement of the light emitting device according to one or more aspects of the present disclosure.

FIGS. 7A to 7C are plan views of an example of the light emitting device according to one or more aspects of the present disclosure.

FIGS. 8A and 8B are cross-sectional views of an example of the light emitting device according to one or more aspects of the present disclosure.

FIGS. 9A to 9C are plan views of an example of a light emitting device according to one or more aspects of the present disclosure.

FIGS. 10A to 10C are cross-sectional views of an example of the light emitting device according to one or more aspects of the present disclosure.

### DESCRIPTION OF THE EMBODIMENTS

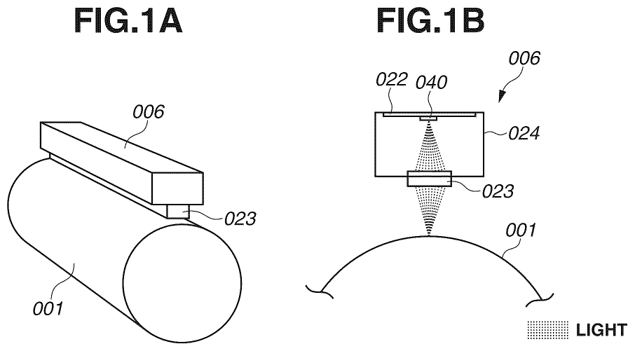

An example of a light emitting device according to a first exemplary embodiment will now be described with reference to FIGS. 1 to 8A and 8B. The following exemplary embodiments are merely examples of the present exemplary embodiment. Numerical values, shapes, materials, components, arrangement and connection forms of the components, and the like do not limit the present exemplary embodiment.

An organic light emitting diode (OLED) will now be described as an example of a light emitting element. The present disclosure is not limited to an OLED and can be applied to current driven type light emitting devices in general such as a light emitting diode (LED).

FIG. 1A is a perspective view of an example of a photosensitive drum 001 and an OLED print head (OLED-PH) 006 (exposure head). FIG. 1B is a cross-sectional view of an example of the photosensitive drum 001 and the OLED-PH 006.

As illustrated in FIGS. 1A and 1B, the OLED-PH 006 is fixed to a position facing a surface of the photosensitive drum 001 by a fixing member, which is not illustrated. The OLED-PH 006 includes a light emitting device 040 that emits light and a printed substrate 022 on which the light emitting device 040 is mounted. The OLED-PH 006 further includes a rod lens array 023 that focuses (concentrates) the light emitted from the light emitting device 040 onto the photosensitive drum 001 and a housing 024 to which the rod lens array 023 and the printed substrate 022 are fixed.

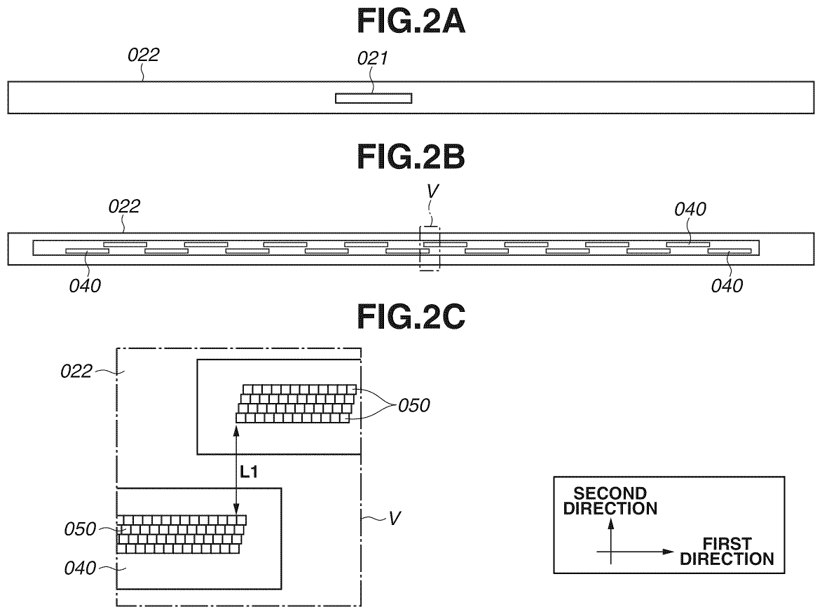

FIGS. 2A and 2B illustrate mounting surfaces on one side and the other side of the printed substrate 022 provided in the OLED-PH 006. FIG. 2C is an enlarged view of an area V illustrated in FIG. 2B. FIG. 2A illustrates a surface of the printed substrate 022 opposite to a surface on which the light emitting device 040 is arranged, and a connector 021 is arranged thereon. The connector 021 can be connected to a control signal cable from an image controller unit and a power cable from a power supply. The control signal cable can include at least one of, for example, a chip select signal line, a clock signal line, an image data signal line, a line synchronization signal line, and a communication signal line.

FIG. 2B illustrates a surface of the printed substrate 022 on which the light emitting devices 040 are mounted. As illustrated in FIG. 2B, 17 pieces of light emitting devices 040 are mounted on the printed substrate 022 in two columns in a staggered arrangement. In each light emitting device 040, 872 pieces of light emitting elements 050 are arranged in a longitudinal direction (first direction) of the light emitting device 040 at a predetermined resolution pitch. In each light emitting device 040, four light emitting elements 050 are arranged in a transverse direction (second direction) of the light emitting device 040 at a predetermined pitch. In other words, the light emitting elements 050 are two-dimensionally arranged in each light emitting device 040. The four light emitting elements 050 arranged in the transverse direction form the same pixel by multiple exposure.

According to the present exemplary embodiment, the above-described resolution pitch of the light emitting device 040 can be set to, for example, 1200 dots per inch (dpi) (approximately 21.16 μm (micrometers)). A distance (array pitch) from one end to the other end in the longitudinal direction of the light emitting elements 050 included in each light emitting device 040 is, for example, about 18.451 mm (millimeters). Here, the array pitch in the longitudinal direction of the light emitting elements refers to, for example, a distance in the longitudinal direction from an end of a first electrode of a light emitting element to an end of a first electrode of a light emitting element adjacent to the light emitting element.

Specifically, the OLED-PH 006 includes, for example, a total of 14,824 pieces of light emitting elements 050 in the longitudinal direction and thus can perform exposure processing corresponding to an image width of about 315 mm (approximately 18.5 mm*17 chips) in the longitudinal direction. In the transverse direction of the light emitting device 040, an array pitch L1 of the light emitting elements 050 of adjacent emitting devices 040 is about 350 μm. By reducing the array pitch L1, the light emitting elements 050 can be arranged at the center of a lens, and light utilization efficiency of the light emitting device 040 can be improved. The array pitch L1 is set based on various variations such as a mounting variation in a mounting apparatus (die bonder) and a variation in a manufacturing process of the light emitting element 050.

The light emitting devices 040 adjacent to each other in the second direction can be arranged such that the light emitting elements 050 included in each of the light emitting devices 040 overlap in the first direction. In a mounting process of the light emitting device 040, positional deviation can occur, and a position of irradiated light can be deviated on the photosensitive drum 001 at a boundary between the light emitting devices 040, resulting in shading of light and formation of an image streak. However, the light emitting elements 050 included in each of the light emitting devices 040 adjacent to each other in the second direction are arranged to overlap with each other in the first direction, so that the boundary between columns of the light emitting elements 050 becomes blurred, and the occurrence of shading and the image streak due to positional deviation of the irradiated light can be suppressed. An overlap amount is calculated from a maximum amount of mounting variation of the mounting apparatus (die bonder) and is set to an amount that does not generate a gap between the light emitting elements 050 included in each of the light emitting devices 040 adjacent to each other in the transverse direction. It is thereby possible to effectively suppress the occurrence of shading or the image streak due to positional deviation of the irradiated light.

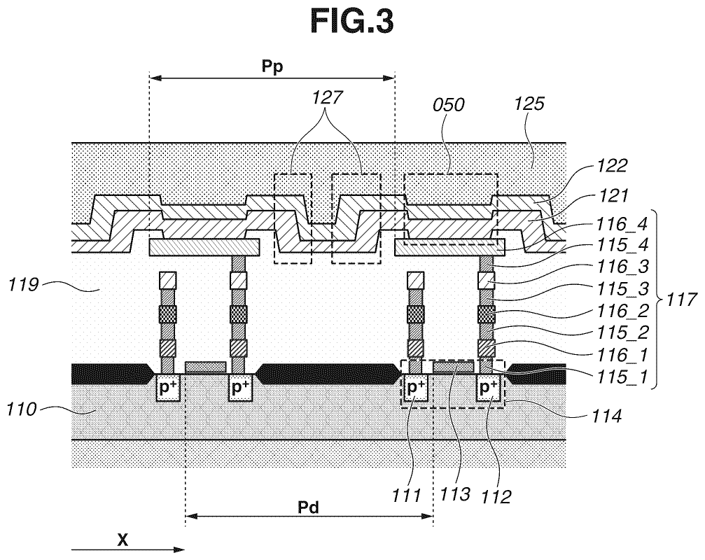

FIG. 3 is a schematic cross-sectional view illustrating an example of the light emitting element and a transistor connected to the light emitting element. The transistor is an example of an active element. FIG. 3 illustrates the light emitting element 050 and a transistor 114. A pixel drive circuit that drives the light emitting element 050 includes, for example, the transistor 114 connected to the light emitting element 050 as illustrated in FIG. 3. The transistor 114 arranged on a silicon substrate 110 is configured with a gate 113, a drain 112, and a source 111 of the transistor. Here, an example of a metal oxide semiconductor field effect transistor (MOSFET) that includes an active layer in a single crystal silicon substrate is described.

There is wiring 117 that electrically connects the drain 112 of the transistor 114 and the light emitting element 050 and is made of a plurality of contact plugs 115_1 to 115_4 and a plurality of metal layers 116_1 to 116_4, and an insulating layer 119 is provided between each wiring 117. FIG. 3 illustrates the insulating layer 119 as a single layer, but the insulating layer 119 can have a laminated structure of a plurality of layers.

The light emitting element 050 is configured with a first electrode 116-4, an organic compound layer 121 including a light emitting layer, and a second electrode 122, and two adjacent first electrodes 116-4 are separated by the insulating layer 119. FIG. 3 illustrates the organic compound layer 121 as a single layer, but the organic compound layer 121 can include a plurality of layers. In the light emitting element 050, the second electrode 122 is a transparent electrode, so that light from the organic compound layer 121 can be extracted to the outside. On the second electrode 122, a protective layer 125 for reducing deterioration of the light emitting element 050 is provided. The second electrode 122 of the light emitting element 050 is shared by a plurality of light emitting elements 050 and serves as a common electrode.

Between each of the light emitting elements 050, a structure 127 having a large step immediately below the organic compound layer 121 also thins the organic compound layer 121 and electrically isolates the two light emitting elements 050 from each other. The second electrode 122 is electrically connected and serves as the common electrode among the plurality of light emitting elements 050. In the light emitting device 040, a combination of the above-described light emitting element 050 and the pixel drive circuit including the transistor 114 is repeatedly arranged in row and column directions.

For example, in FIG. 3, an array pitch Pp of the light emitting elements 050 in an X direction refers to a distance from the end (here, the left end) of the first electrode 116-4 of the light emitting element 050 illustrated in FIG. 3 to the end on the same side (here, the left side) of the first electrode 116-4 of the adjacent light emitting element 050. In a case where one pixel drive circuit is regarded as a repeating unit, an array pitch Pd of the pixel drive circuits in the X direction can also be a distance from one end to the other end of the repeating unit that is defined such that a corresponding pixel drive circuit is included in the repeating unit arranged in the X direction. For example, the array pitch Pd can also be a distance between the centers of two circuit isolation portions arranged in the X direction across a certain pixel drive circuit. Alternatively, for example, the array pitch Pd can also be a distance from an end (here, the left end) of a gate electrode of the transistor 114 illustrated in FIG. 3 to an end on the same side (here, the left side) of the gate electrode of the transistor 114 of the adjacent pixel drive circuit.

A method of electrical connection with electrodes (a source electrode and a drain electrode) included in the transistor 114 is not limited to a form illustrated in FIG. 3. Either the source electrode or the drain electrode of the transistor 114 can be electrically connected according to polarity of the first electrode 116_4 or polarity of the transistor 114.

The transistor 114 is not limited to a transistor using a single crystal silicon wafer and can be a thin film transistor (TFT) including an active layer on an insulating surface of a substrate. Examples of materials for the active layer include single crystal silicon, non-single crystal silicon such as amorphous silicon and microcrystalline silicon, and non-single crystal oxide semiconductors such as indium zinc oxide and indium gallium zinc oxide.

Using a transistor having a single crystal silicon wafer as the transistor 114 makes it possible to miniaturize the pixel drive circuit and increase a speed of the circuit including a transistor.

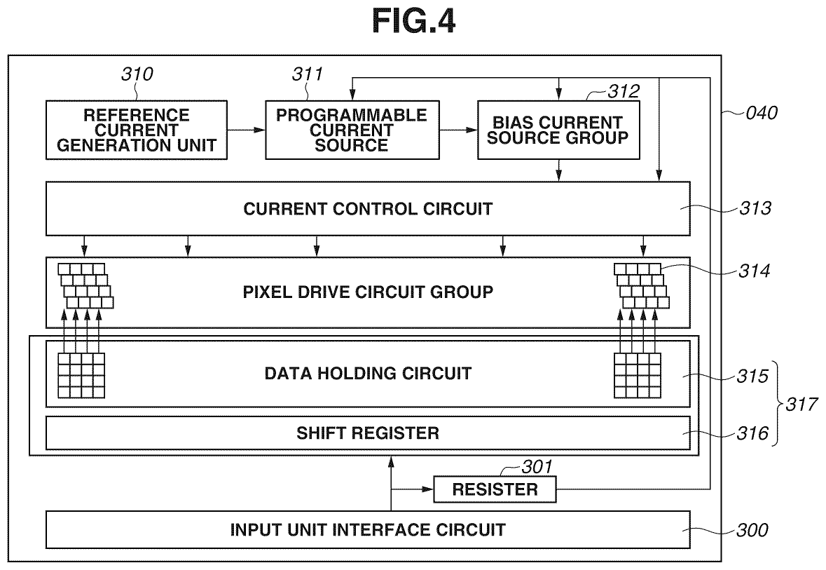

FIG. 4 is an example of a circuit block diagram of the light emitting device 040 according to the present exemplary embodiment. The light emitting device 040 includes an input unit interface circuit 300, a resister 301, a reference current generation unit 310, a programmable current source 311, a bias current source group 312, a current control circuit 313, a pixel drive circuit group 314, and a horizontal scanning circuit 317. The horizontal scanning circuit 317 includes a data holding circuit 315 and a shift register 316. The input unit interface circuit 300 receives, from an external interface, mode information for accessing the power supply and the resister and information related to image data, and outputs a data signal to the resister 301 and the horizontal scanning circuit 317.

The programmable current source 311 uses an output current of the reference current generation unit 310 as a reference, and outputs a current corresponding to a digital value supplied from the resister 301 to the bias current source group 312. A driving current of the pixel drive circuit group 314 is controlled by a setting value of the resister 301. The bias current source group 312 supplies an output current corresponding to the setting value set in the resister 301 to the current control circuit 313. The current control circuit 313 generates a bias voltage for the pixel drive circuit group 314.

The shift register 316 controls a timing for the light emitting element to emit light or not based on a data signal from the input unit interface circuit 300. The data holding circuit 315 holds information corresponding to each light emitting element and determines whether the light emitting element emits light or not.

The pixel drive circuit group 314 is connected to the light emitting element, and its driving current is determined by the bias voltage supplied from the current control circuit 313. The pixel drive circuit group 314 controls the light emitting element to emit light or not based on a signal supplied from the data holding circuit 315. The pixel drive circuit group 314 includes a plurality of pixel drive circuits, and each of the plurality of pixel drive circuits drives the corresponding light emitting element among the plurality of light emitting elements.

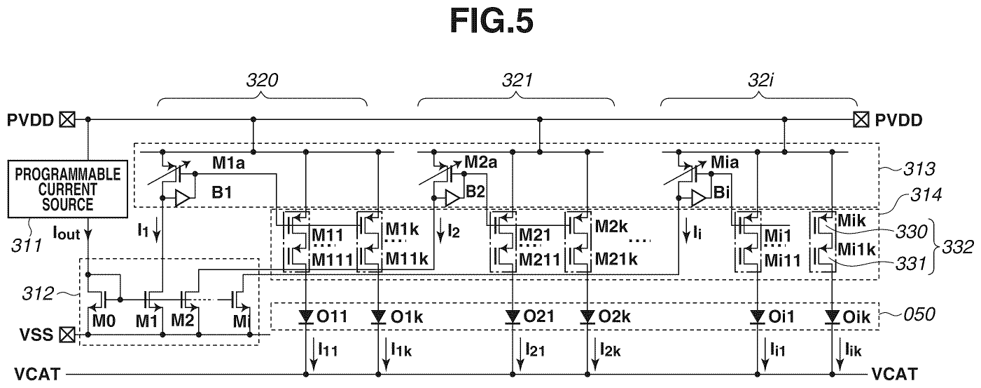

FIG. 5 illustrates an example of a drive unit of the light emitting element. A method for adjusting a light emitting current of the light emitting element and light emitting control will now be described.

As illustrated in FIG. 5, a pixel drive circuit 332 of the light emitting element 050 includes a first transistor 330 and a second transistor 331 that are connected in series. Here, all transistor sizes are assumed to be substantially the same for the sake of explanation. The bias current source group 312 is configured with transistors M0 to Mi. The current control circuit 313 is configured with transistors M1a to Mia and buffers B1 to Bi connected between gate-drain terminals of the transistors M1a to Mia.

The pixel drive circuit group 314 includes a first group of transistors M11 to Mik and a second group of transistors M111 to Mi1k. Each of the transistors M111 to Mi1k in the second group of transistors is connected in series to corresponding light emitting elements O11 to Oik. A plurality of current control circuits 313 is divided into a plurality of blocks 320 to 32i.

An output current Iₒᵤₜ of the programmable current source 311 is connected to a drain terminal of the transistor M0 in the bias current source group 312. The transistor M0 is diode-connected, and a voltage Vbn to be determined by the current Iₒᵤₜ is commonly applied to gates of the transistors M0 to Mi, so that the current Iₒᵤₜ has the same value as those of currents I₁ to Iᵢ illustrated in FIG. 5.

In the block 320, a drain terminal of the transistor M1a forming the current control circuit 313 is connected in series to a drain terminal of the transistor M1. A gate terminal of the transistor M1a is connected to the drain terminal via the buffer B1. The buffer B1 is a voltage buffer with a gain of 1 and serves to absorb variation in gate potential of the first group of transistors M11 to M1k caused by a light emission control operation of the pixel drive circuit 332.

The transistor M1a is diode-connected via the buffer B1, and a voltage V_{bp1} determined by the current I₁ is applied to the gates of the first transistors M11 to M1k in common as the gate potential. The first transistors M11 to M1k have the same gate-source voltage and can supply the same driving currents I₁₁ to I₁ₖ to each of the light emitting elements O11 to O1k. The first transistor functions as a constant current source.

The data holding circuit 315 applies a drive voltage to the gates of the second transistors M111 to M11k to control whether to supply a current to the light emitting element. The second transistor functions as a switch.

When the pixel drive circuit 332 is affected by the power fluctuation, the current for driving the light emitting element changes, resulting in unevenness in an output image of an image forming apparatus. By arranging the transistor M0 and the transistors M1 to Mi close to each other to form a current mirror circuit configuration, the configuration is less susceptible to an effect of a fluctuation in the power line, so that adopting the circuit configuration according to the present exemplary embodiment is advantageous to suppress unevenness. Similarly, by arranging the transistor M1a and the first group of transistors M11 to M1k close to each other to form a current mirror circuit configuration, the configuration is advantageous to suppress unevenness.

Similarly, the light emitting elements 021 to O2k are driven by the first transistors M21 to M2k and the second transistors M211 to M21k to emit light. The light emitting elements Oi1 to Oik are also driven by the first transistors Mi1 to Mik and the second transistors Mi11 to Mi1k to emit light.

According to the present exemplary embodiment, it is assumed that each transistor size is substantially the same, but each transistor size can be adjusted by the resister 301. If the transistor sizes of the transistors M1 to Mi in the bias current source group 312 are adjusted by a resister setting, a mirror ratio with respect to the transistor M0 is changed, and the current of the pixel drive circuit 332 can be roughly adjusted. Similarly, if the transistor sizes of the transistors M1a to Mia in the current control circuit 313 can be adjusted by the resister setting, the current of the pixel drive circuit 332 can be roughly adjusted.

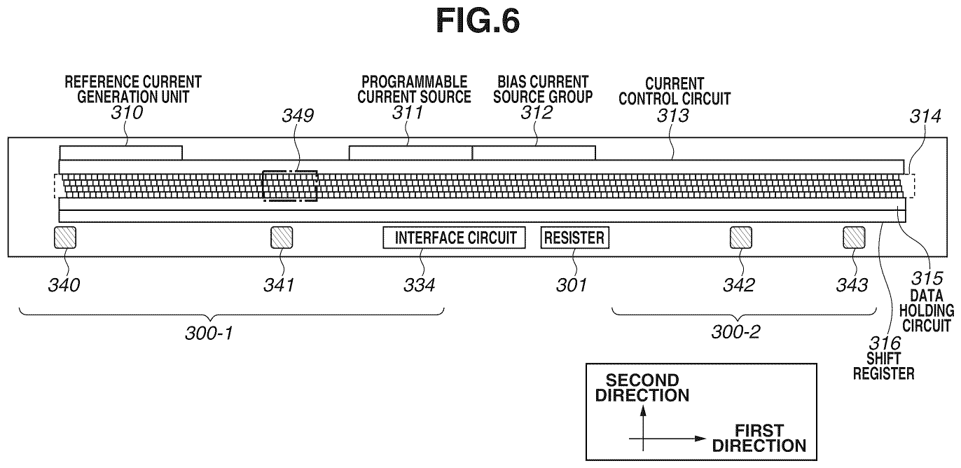

FIG. 6 is an example of a plan layout drawing of the circuit block and the light emitting element of the light emitting device 040 in FIG. 4. In FIG. 6, the substrate is illustrated as an example of a rectangle having long sides extending in the first direction and short sides extending in the second direction, but can be another polygon such as a parallelogram.

In input unit interface circuits 300-1 and 300-2, terminals 340 to 343 for inputting power supply, a control signal, and the like of the light emitting device 040 and an interface circuit 334 are arranged along the first direction. In the longitudinal direction, 872 pieces of light emitting elements 050 are arranged at a predetermined resolution pitch. One row includes 872 pieces of light emitting elements, and four rows of light emitting elements are arranged in the transverse direction. The pixel drive circuit 332 of each light emitting element 050 is arranged on a lower layer (substrate side) of the light emitting element 050. The resister 301, the shift register 316, and the data holding circuit 315 are controlled by the input unit interface circuit 300 and are thus arranged on a plane near the input unit interface circuit 300.

The data holding circuit 315 is responsible for light emission control on the light emitting element, and the current control circuit 313 is responsible for control of a light emission amount of the light emitting element, it is therefore necessary to wire for a control signal from each circuit block to the pixel drive circuit group 314. The current control circuit 313, the pixel drive circuit group 314, and the data holding circuit 315 are arranged in this order in the transverse direction. A control wire of the data holding circuit 315 can thereby be wired in the transverse direction from a side of the pixel drive circuit group 314 extending in the longitudinal direction. A control wire of the current control circuit 313 can also be wired in the transverse direction from the other side of the pixel drive circuit group 314 extending in the longitudinal direction. The control wires of the data holding circuit 315 and the current control circuit 313 can thus be easily connected.

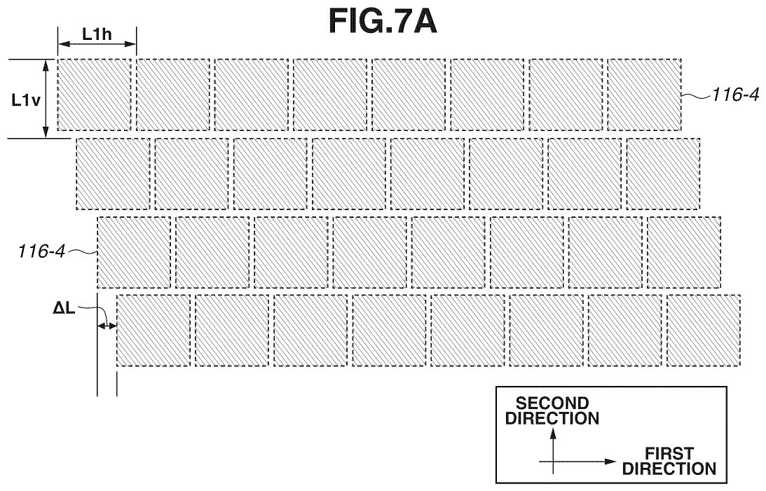

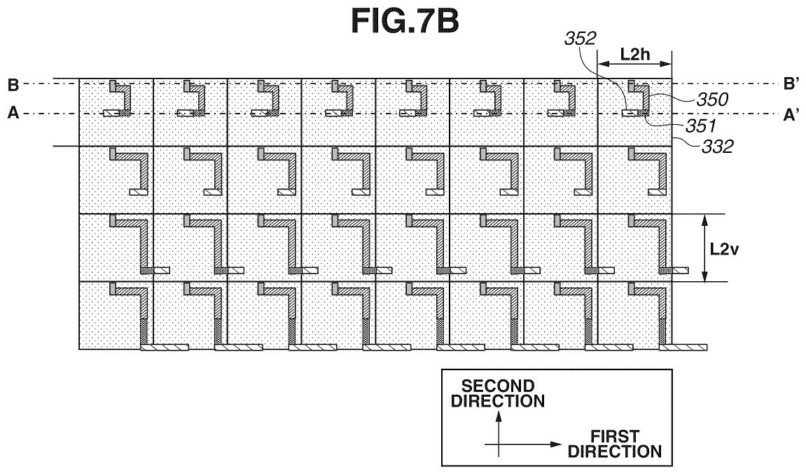

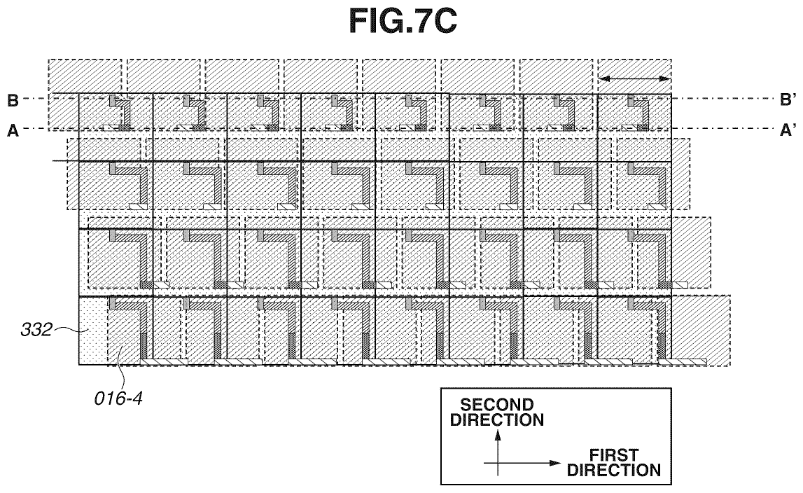

FIGS. 7A to 7C illustrate an example of arrangement of the light emitting elements and the pixel drive circuits in an area 349 illustrated in FIG. 6. In FIGS. 7A to 7C, the light emitting device 040 includes a plurality of light emitting elements arranged in M columns and N rows on a main surface of the substrate and a plurality of pixel drive circuits arranged in M columns and N rows for driving corresponding light emitting elements among the plurality of light emitting elements. Here, M and N are integer greater than or equal to 1, and the N rows extend in the first direction, and the M columns extend in the second direction intersecting the first direction. A first array pitch of a first light emitting element and a second light emitting element adjacent to each other in the first direction parallel to the N rows among the plurality of light emitting elements is different from a second array pitch of a first pixel drive circuit and a second pixel drive circuit adjacent to each other in the first direction among the plurality of pixel drive circuits.

The light emitting device 040 will now be described more specifically with reference to FIGS. 7A to 7C. FIG. 7A illustrates an example of arrangement of the first electrodes 116-4 of the light emitting elements arranged in a matrix of four rows and eight columns in the area 349 in FIG. 6.

The first electrodes 116-4 of the light emitting elements belonging to an N-th row are arranged at a pitch L1h in the longitudinal direction. The first electrodes 116-4 of the light emitting elements in the N-th and (N+1)-th rows are arranged at an array pitch L1v in the transverse direction. The first electrodes 116-4 of the light emitting elements arranged in the N-th row and the first electrodes 116-4 of the light emitting elements arranged in the (N+1)-th row are arranged with a shift of ΔL (L1h/4) in the longitudinal direction (N is 1 or more and less than 3). Since the first electrodes 116-4 are arranged with the shift of ΔL in the longitudinal direction, an exposed image having a higher resolution than the array pitch L1h of the first electrodes 116-4 can be formed on the photosensitive drum. Here, a design value of ΔL is not limited to L1h/4, and an appropriate value can be selected between zero and L1h depending on a balance between the resolution and a required amount of light. Here, an example of four light emitting elements in one column is described, but the present exemplary embodiment is not limited to this configuration. For example, in a case where I (I is an integer greater than or equal to 2) pieces of light emitting elements are arranged in one column, a shift amount ΔL in the longitudinal direction of the first electrodes of the light emitting elements adjacent to each other in the row direction can also be L1h/I.

FIG. 7B illustrates an example of arrangement of the pixel drive circuits connected to the first electrodes 116-4 of the light emitting elements in FIG. 7A. The pixel drive circuits 332 arranged in a matrix of four rows and eight columns are arranged at an array pitch L2h in the longitudinal direction and at an array pitch L2v in the transverse direction.

FIG. 7C illustrates a planar relationship when each element is stacked by overlapping the plan view in FIG. 7A with the plan view in FIG. 7B. In a plan view, the pixel drive circuit and the light emitting element have at least a partially overlapping area. The overlapping area can shorten the wiring connecting the pixel drive circuit and the light emitting element, and simplify a layout. The light emitting element and the pixel drive circuit of the light emitting element are typically arranged at the same pitch. In contrast, according to the present exemplary embodiment, the array pitch L1h of the first electrode of the light emitting element in the longitudinal direction is different from the array pitch L2h of the pixel drive circuit.

In a case where priority is given to the resolution, the array pitch of the light emitting element can be set narrower than the array pitch of the pixel drive circuit, and in a case where priority is given to the amount of light, the array pitch of the light emitting element can be set wider than the array pitch of the pixel drive circuit. Since design requirements are different between the light emitting element and the pixel drive circuit, designing the light emitting element and the pixel drive circuit to appropriate sizes according to the respective requirements makes it possible to achieve characteristics of the light emitting device and cost reduction.

An amount of light emitted by one light emitting element using an OLED as a light emitting source of an image forming apparatus is not sufficient in some cases. In order to increase the amount of light emitted by the light emitting device, it is necessary to design to form a large light emitting element within a range that satisfies a predetermined resolution pitch. In contrast, an OLED is susceptible to heat generation, and a current that can flow per unit area is small compared with a current supply capability per unit area of the pixel drive circuit. If the pixel drive circuit is made as large as the light emitting element, a chip size increases, a yield of the light emitting device per substrate is reduced, and cost reduction is hindered.

According to the present exemplary embodiment, the array pitch L1h (first array pitch) of the first electrode is larger than the array pitch L2h (second array pitch) of the pixel drive circuit in the longitudinal direction. In other words, a size of the pixel drive circuit can be made smaller with respect to the light emitting element in the longitudinal direction. Alternatively, a size of the light emitting element can be made larger with respect to the pixel drive circuit. For example, a difference between the array pitch L1h and the array pitch L2h in the longitudinal direction is less than or equal to a value obtained by dividing a distance in the longitudinal direction from one end to the other end of an area where the light emitting elements are arranged by the number of columns of the pixels.

In this way, another circuit is arranged in a space obtained by reducing the size of the pixel drive circuit in the longitudinal direction, so that the light emitting device can be made small, and a cost reduction effect can be acquired. Thus, an advantage of using the silicon substrate can further be provided. Further, compared with a case where the light emitting element is arranged according to the pixel drive circuit, an area of the light emitting element can be made larger, and a light emission amount for exposure can be increased.

Similarly, the array pitch L1v (first array pitch) of the first electrode is larger than the array pitch L2v (second array pitch) of the pixel drive circuit in the transverse direction (second direction). Specifically, a fifth array pitch of the first light emitting element and a third light emitting element that are adjacent to each other in the second direction among the plurality of light emitting elements is different from a sixth array pitch of the first pixel drive circuit and a third pixel drive circuit that are adjacent to each other in the second direction among the plurality of pixel drive circuits. More specifically, the fifth array pitch is larger than the sixth array pitch.

In this way, a size of the pixel drive circuit in the transverse direction is reduced, so that the light emitting device can be made small, and the cost reduction effect can be acquired. Further, the size of the light emitting element is made larger, and accordingly the light emission amount can be increased. The light emitting element and the pixel drive circuit are arranged in an appropriate positional relationship according to what is required for each in the light emitting device, so that it is possible to miniaturize the light emitting device or improve its performance.

A side of the first electrode 116-4 of the light emitting element extending in the longitudinal direction and a side of the pixel drive circuit 332 extending in the longitudinal direction can or can not overlap. The arrangement and size of the light emitting element are determined according to an amount of light required by the photosensitive drum, and can thus be appropriately set according to each requirement.

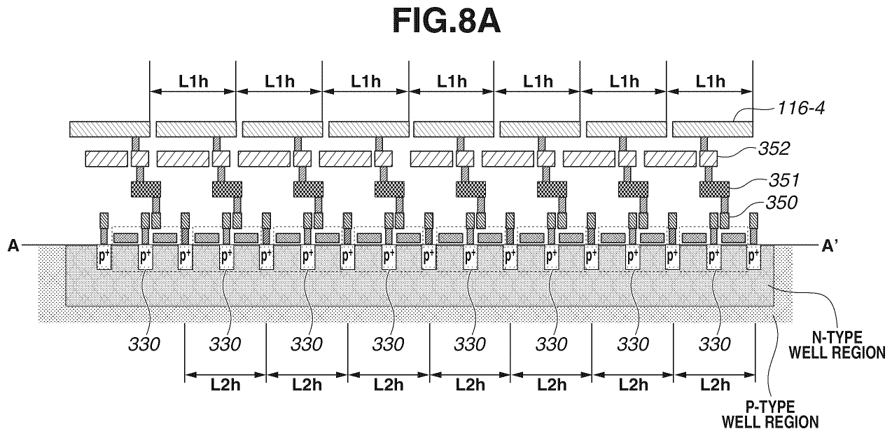

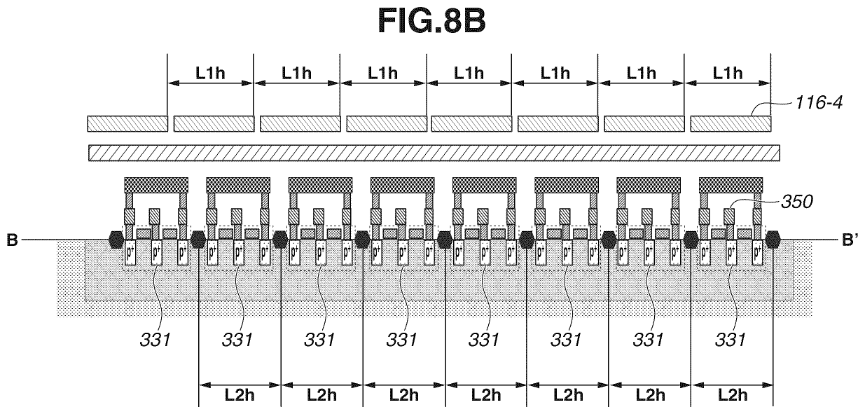

FIG. 8A is a schematic cross-sectional view taken along a line A-A′ illustrated in FIG. 7C. The first transistors 330 of the pixel drive circuits 332 are arranged at the array pitch L2h in the longitudinal direction. The first electrodes 116-4 of the light emitting elements 050 are arranged at the array pitch L1h. Metal wires 350 to 352 electrically connected to the second transistor 331 of the pixel drive circuit 332 pass through an upper layer of the first transistor 330 and are connected to the first electrode 116-4 of the light emitting element 050 via a contact hole.

FIG. 8B is a schematic cross-sectional view taken along a line B-B′ illustrated in FIG. 7C. The second transistors 331 of the pixel drive circuits 332 are arranged at the same array pitch L2h as that of the first transistor 330. A drain terminal of the second transistor 331 is electrically connected to the metal wire 350 via the contact hole.

By adopting the configuration according to the present exemplary embodiment, it is possible to reduce the size of the light emitting device and to increase the yield of the light emitting device per substrate, so that an effect of manufacturing the light emitting device at low cost can be acquired.

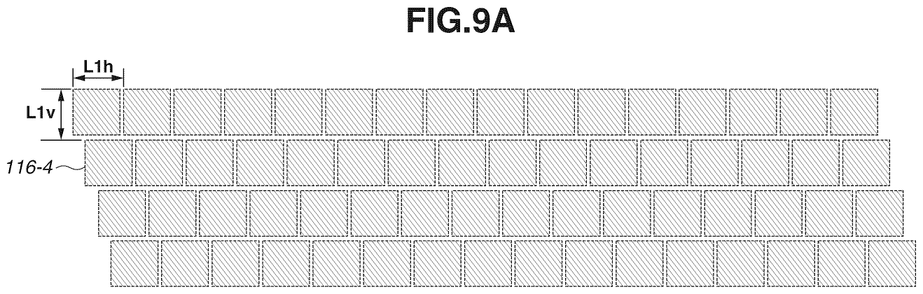

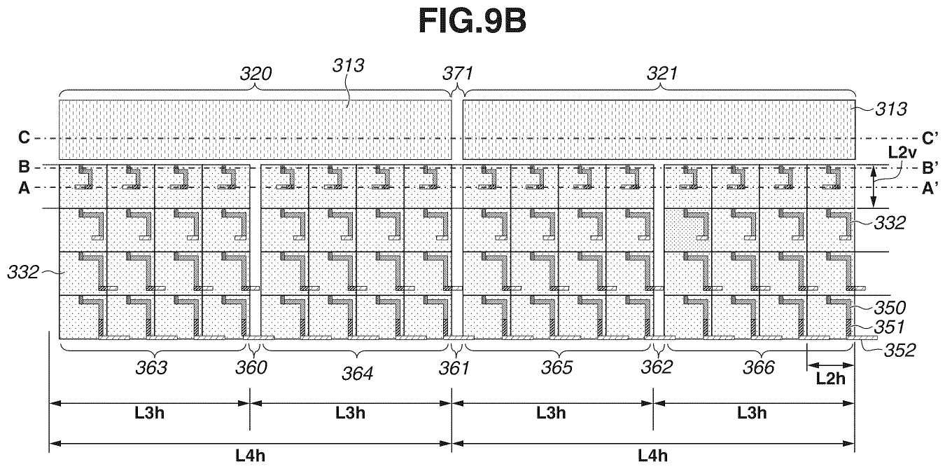

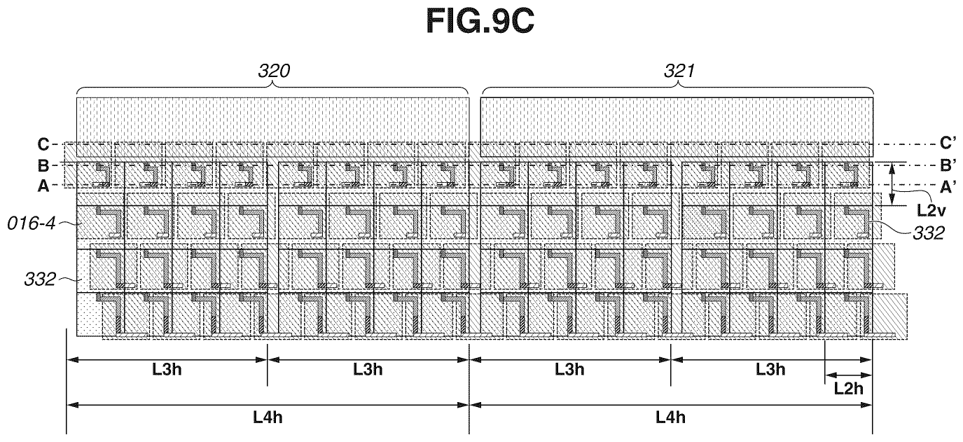

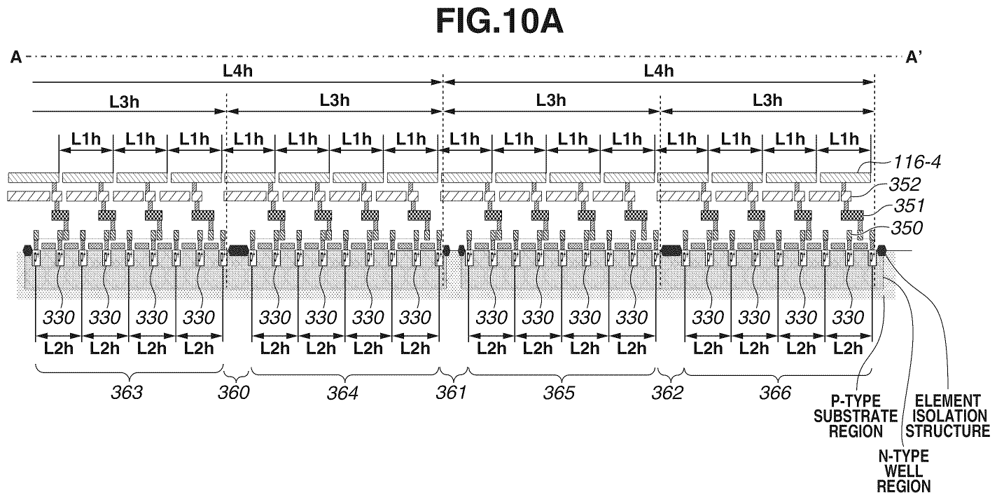

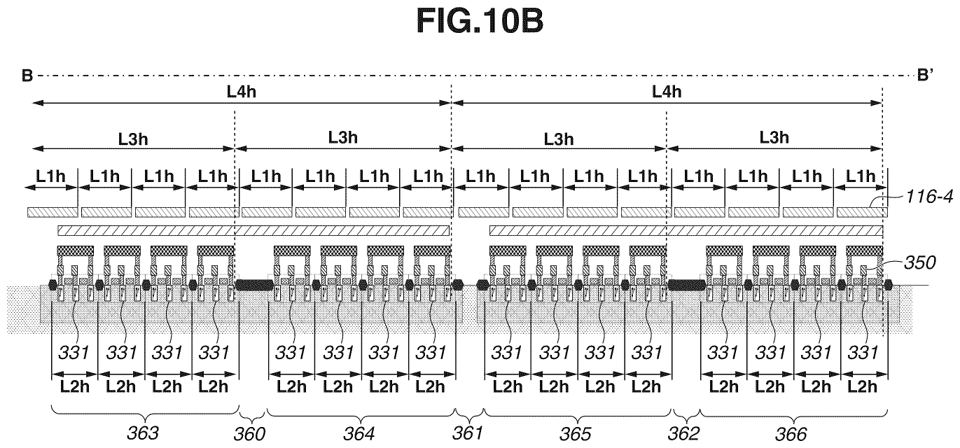

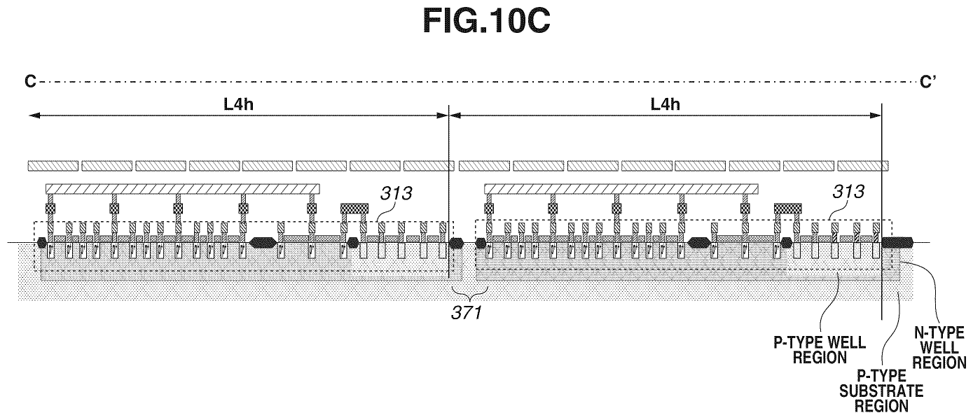

A light emitting device according to a second exemplary embodiment will now be described with reference to FIGS. 9A to 9C and 10A to 10C. Only parts different from the above-described overview and the first exemplary embodiment will be described, similar parts will be denoted by the same reference numerals, and the descriptions thereof will be omitted.

FIG. 9A is an example of an arrangement of the first electrodes 116-4 of the light emitting elements 050 arranged in a matrix in the area 349 in FIG. 6.

FIG. 9B is an example of an arrangement of the pixel drive circuits 332 connected to the first electrodes 116-4 of the light emitting element 050. Compared with FIG. 7B, the plurality of current control circuits 313 is added in FIG. 9B.

The plurality of pixel drive circuits 332 is divided into a plurality of pixel drive circuit blocks 363 to 366 in the first direction by a plurality of circuit isolation portions 360 to 362 and arranged at an array pitch L3h.

In other words, the circuit isolation portions 360 to 362 are arranged in the first direction at the array pitch L3h (third array pitch). The third array pitch can be, for example, a distance in the first direction from an end on one side (e.g., the left side) of one circuit isolation portion to an end on the one side (here, the left side) of a circuit isolation portion that is adjacent to the circuit isolation portion across one pixel drive circuit block.

The plurality of current control circuits 313 is divided into a plurality of blocks in the first direction by the block isolation portion 371 and arranged at an array pitch L4h (fourth array pitch). The fourth array pitch can be, for example, a distance in the first direction from an end on one side (e.g., the left side) of one block isolation portion to an end on the one side (here, the left side) of a circuit isolation portion that is adjacent to the block isolation portion across one block.

The third array pitch is smaller than the fourth array pitch, and the plurality of pixel drive circuit blocks is arranged in an area corresponding to one block of the current control circuit 313 in the second direction. The block isolation portion 371 and the circuit isolation portion 361 are arranged side by side in the second direction (short side direction). Thus, for example, first circuit isolation portions included in the plurality of circuit isolation portions are arranged at positions overlapping with first block isolation portions included in a plurality of block isolation portions in the second direction. A length of the first circuit isolation portion in the first direction is smaller than a length of the first block isolation portion in the first direction.

In a case where a positional deviation between the light emitting element and the pixel drive circuit electrically connected to the light emitting element becomes large, resistance of wiring connecting both elements increases, and current accuracy of the pixel drive circuit deteriorates. The array pitch L3h of the pixel drive circuit block is set to be an integer multiple of the array pitch L1h of the light emitting element, so that the positional deviation between the light emitting element and the pixel drive circuit can be suppressed within a certain range.

By dividing the pixel drive circuit into blocks and arranging the current control circuit near the pixel drive circuit for each block, an effect of power shading can be reduced. By setting the array pitch L2h of the pixel drive circuit shorter compared with the array pitch L1h of the light emitting element, an area for arranging isolation portions such as the circuit isolation portion 361 and the block isolation portion 371 can be secured. The block isolation portion is arranged between the blocks 320 and 321, so that a back gate of the transistor can be biased at an appropriate potential for each block, and this is advantageous in terms of current accuracy of the pixel drive circuit compared with a case where the blocks are not isolated.

Reducing the number of current control circuits is advantageous in terms of power consumption of the light emitting device, so that two pixel drive circuit blocks are driven by one current control circuit according to the present exemplary embodiment. In a case where a large current is required to drive the light emitting elements belonging to the pixel drive circuit block, it is desirable to drive one pixel drive circuit block by one current control circuit in order to reduce the effect of power shading. It is only necessary that the array pitch L3h of the pixel drive circuit blocks is less than or equal to the array pitch L4h of the current control circuit, and the array pitches of both circuits are set taking into consideration the power consumption of the light emitting device, the driving current of the light emitting element, and the current accuracy of the pixel drive circuit.

FIG. 9C illustrates a planer relationship in a case where the plan view in FIG. 9A and the plan view in FIG. 9B are overlapped with each other to stack the respective elements. As illustrated in FIG. 9C, at least a part of the light emitting element overlaps with the current control circuit in a plan view of (the main surface of) the substrate. Since the array pitch of the pixel drive circuit is smaller than the array pitch of the light emitting element in the transverse direction (second direction), a space is generated in a lower layer of the light emitting element. By arranging at least a part of the current control circuit in this space, the light emitting device can be miniaturized by the amount that the current control circuit and the light emitting element overlap compared with a case where the current control circuit and the light emitting element are arranged so as not to overlap. In the plan view, the light emitting element can also overlap at least one of the circuit isolation portions.

Since a plurality of the light emitting devices 040 is arranged in a staggered arrangement in the OLED-PH 006, the light emitting element 050 is arranged at a position away from the center of the rod lens array 023 in the transverse direction in a plan view. If the light emitting element 050 is brought closer to an end of a long side of the light emitting device 040, the light emitting element 050 is brought closer to the center of the rod lens array 023, which is advantageous for increasing an amount of exposure light on the photosensitive drum. According to the present exemplary embodiment, there is an area where a part of the light emitting element 050 (or the first electrode 116-4) overlaps with the current control circuit 313 in a plan view, so that it is possible to bring the light emitting element 050 closer to the end of the long side, which is advantageous for increasing the amount of exposure light. A width of the overlapping area in the transverse direction is desirably less than or equal to an overlapping width L1v.

FIG. 10A is a schematic cross-sectional view taken along a line A-A′ illustrated in FIG. 9C. The first transistors 330 of the pixel drive circuit 332 are arranged in the longitudinal direction at the array pitch L2h, and the pixel drive circuit blocks configured with the plurality of pixel drive circuits are arranged at the array pitch L3h.

According to the present exemplary embodiment, the circuit isolation portions 360 and 362 have a structure in which an element isolation structure is arranged, and the circuit isolation portion 361 has a structure in which a well of different polarity from a well in which the first transistor is arranged is arranged.

FIG. 10B is a schematic cross-sectional view taken along a line B-B′ illustrated in FIG. 9C. The second transistors 331 of the pixel drive circuits 332 are arranged in the longitudinal direction at the array pitch L2h, and the pixel drive circuit blocks configured with the plurality of pixel drive circuits are arranged at the array pitch L3h. According to the present exemplary embodiment, a length in the longitudinal direction of the element isolation structure of the circuit isolation portions 360 and 362 is longer than a length in the longitudinal direction of an element isolation structure between the second transistors 331.

FIG. 10C is a schematic cross-sectional view taken along a line C-C′ illustrated in FIG. 9C. The current control circuits 313 are arranged in the longitudinal direction at the array pitch L4h. In the block isolation portion 371 of the current control circuit, a well of different polarity from the well in which the first transistor is arranged is arranged.

The configuration described according to the present exemplary embodiment is adopted, and thus the light emitting element and the pixel drive circuit can be arranged in a suitably positional relationship, and an amount of light incident on the photosensitive drum can be increased. Accuracy of driving current of the pixel drive circuit that drives each light emitting element can also be improved. It is therefore possible to provide a configuration that is advantageous in terms of amount of light and uniformity as a light source device for an image forming apparatus.

It is possible to provide a light emitting device in which a light emitting element and a pixel drive circuit are arranged in a suitably positional relationship.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-093958, filed Jun. 10, 2024, which is hereby incorporated by reference herein in its entirety.

What is claimed is:

1. A light emitting device comprising:
a plurality of light emitting elements arranged on a main surface of a substrate in M columns and N rows; and
a plurality of pixel drive circuits arranged in M columns and N rows and configured to drive a corresponding light emitting element among the plurality of light emitting elements,
wherein M and N are integers greater than or equal to one,
wherein the N rows extend in a first direction and the M columns extend in a second direction, and
wherein a first array pitch of a first light emitting element and a second light emitting element adjacent to each other in the first direction among the plurality of light emitting elements is different from a second array pitch of a first pixel drive circuit and a second pixel drive circuit adjacent to each other in the first direction among the plurality of pixel drive circuits.

2. The light emitting device according to claim 1, wherein at least a part of the first light emitting element overlaps with the first pixel drive circuit in a plan view with respect to the main surface.

3. The light emitting device according to claim 1, wherein the first array pitch is larger than the second array pitch.

4. The light emitting device according to claim 1, wherein the substrate has a long side along the first direction and a short side along the second direction intersecting the first direction.

5. The light emitting device according to claim 1, wherein each of the plurality of pixel drive circuits includes a transistor configured to drive the corresponding light emitting element.

6. The light emitting device according to claim 1, wherein, in a plan view with respect to the main surface, the plurality of pixel drive circuits is divided into a plurality of pixel drive circuit blocks in the first direction by a plurality of circuit isolation portions.

7. The light emitting device according to claim 6, wherein, in a plan view with respect to the main surface, the light emitting element overlaps with one of the circuit isolation portions.

8. The light emitting device according to claim 1, further comprising a current control circuit adjacent to the plurality of pixel drive circuits in the second direction,
wherein, in a plan view with respect to the main surface, the current control circuit is divided into a plurality of blocks in the first direction by a plurality of block isolation portions.

9. The light emitting device according to claim 1, further comprising a current control circuit adjacent to the plurality of pixel drive circuits in the second direction,
wherein, in a plan view with respect to the main surface, the plurality of pixel drive circuits is divided into a plurality of pixel drive circuit blocks in the first direction by a plurality of circuit isolation portions,
wherein the plurality of circuit isolation portions is arranged at a third array pitch in the first direction, and the plurality of block isolation portions is arranged at a fourth array pitch in the first direction, and
wherein the third array pitch is smaller than the fourth array pitch.

10. The light emitting device according to claim 1, further comprising a current control circuit adjacent to the plurality of pixel drive circuits in the second direction,
wherein, in a plan view with respect to the main surface, the plurality of pixel driving circuits are divided into a plurality of pixel driving circuit blocks in the first direction by a plurality of circuit isolation portions,
wherein, in the plain view, the current control circuit is divided into a plurality of blocks in the first direction by a plurality of block isolation portions, and
wherein a first circuit isolation portion included in the plurality of circuit isolation portions is arranged at a position overlapping with a first block isolation portion included in the plurality of block isolation portions in the second direction.

11. The light emitting device according to claim 10, wherein a length of the first circuit isolation portion in the first direction is smaller than a length of the first block isolation portion in the first direction.

12. The light emitting device according to claim 1, wherein a fifth array pitch of the first light emitting element and a third light emitting element adjacent to each other in the second direction among the plurality of light emitting elements is different from a sixth array pitch of the first pixel drive circuit and a third pixel drive circuit adjacent to each other in the second direction among the plurality of pixel drive circuits.

13. The light emitting device according to claim 12, wherein the fifth array pitch is larger than the sixth array pitch.

14. The light emitting device according to claim 1, wherein the substrate has a short side along the first direction and a long side along the second direction intersecting the first direction.

15. A light emitting device comprising:
a plurality of light emitting elements arranged on a main surface of a substrate in a matrix; and
a plurality of pixel drive circuits arranged in a matrix and each including a transistor configured to drive a corresponding light emitting element among the plurality of light emitting elements; and
a current control circuit adjacent to a part of the plurality of pixel drive circuits in a first direction in a plan view with respect to the main surface,
wherein, in the plan view, at least a part of the plurality of light emitting elements overlaps with the current control circuit.

16. The light emitting device according to claim 15, wherein the substrate has a short side extending in the first direction and a long side extending in a second direction intersecting the first direction.

17. The light emitting device according to claim 15,
wherein, in the plan view, the plurality of pixel drive circuits is divided into a plurality of pixel drive circuit blocks by a plurality of circuit isolation portions in a second direction intersecting the first direction,
wherein, in the plan view with respect to the main surface, the current control circuit is divided into a plurality of blocks in the second direction by a plurality of block isolation portions,
wherein the plurality of circuit isolation portions is arranged at a third array pitch in the second direction, and the plurality of block isolation portions is arranged at a fourth array pitch in the second direction, and
wherein the third array pitch is smaller than the fourth array pitch.

18. The light emitting device according to claim 15, wherein a first circuit isolation portion included in a plurality of circuit isolation portions is arranged at a position overlapping with a first block isolation portion included in a plurality of block isolation portions in the first direction.

19. The light emitting device according to claim 18, wherein a length of the first circuit isolation portion in a second direction intersecting the first direction is smaller than a length of the first block isolation portion in the second direction.

20. An image forming apparatus comprising:
a photosensitive drum; and
an exposure head arranged to face the photosensitive drum,
wherein the exposure head includes the light emitting device comprising:
a plurality of light emitting elements arranged on a main surface of a substrate in M columns and N rows; and
a plurality of pixel drive circuits arranged in M columns and N rows and configured to drive a corresponding light emitting element among the plurality of light emitting elements,
wherein M and N are integers greater than or equal to one,
wherein the N rows extend in a first direction and the M columns extend in a second direction, and
wherein a first array pitch of a first light emitting element and a second light emitting element adjacent to each other in the first direction among the plurality of light emitting elements is different from a second array pitch of a first pixel drive circuit and a second pixel drive circuit adjacent to each other in the first direction among the plurality of pixel drive circuits; and
a lens array configured to focus light emitted from the light emitting device to the photosensitive drum.

21. An image forming apparatus comprising:
a photosensitive drum; and
an exposure head arranged to face the photosensitive drum,
wherein the exposure head includes the light emitting device comprising:
a plurality of light emitting elements arranged on a main surface of a substrate in a matrix; and
a plurality of pixel drive circuits arranged in a matrix and each including a transistor configured to drive a corresponding light emitting element among the plurality of light emitting elements; and
a current control circuit adjacent to a part of the plurality of pixel drive circuits in a first direction in a plan view with respect to the main surface,
wherein, in the plan view, at least a part of the plurality of light emitting elements overlaps with the current control circuit; and
a lens array configured to focus light emitted from the light emitting device to the photosensitive drum.
